(19) United States
(12) Patent Application Publication
(10) Pub. No.: US 2007/0268746 A1
(43) Pub. Date: Nov. 22, 2007

(54) Nonvolatile memory device performing 2-bit operation and method of manufacturing the same

(75) Inventors: Byung-yong Choi, Suwon-si (KR); Byung-gook Park, Seocho-gu (KR); Dong-gun Park, Seongnam-si (KR); Choong-ho Lee, Seongnam-si (KR)

Correspondence Address: LEE & MORSE, P.C., 3141 FAIRVIEW PARK DRIVE, SUITE 500, FALLS CHURCH, VA, 22042, US

(73) Assignee: Samsung Electronics Co., Ltd.

(21) Appl. No.: 11/657,133

(22) Filed: Jan. 24, 2007

(30) Foreign Application Priority Data
May 16, 2006 (KR) 10-2006-0043948

(51) Int. Cl. G11C 11/34

(52) U.S. Cl. 365/185.05

(57) ABSTRACT

A nonvolatile memory device includes active regions extending in a word line direction in a semiconductor substrate and defined in a first zigzag pattern; gates extending in the word line direction and formed in a second zigzag pattern that repeatedly intersects the active regions in symmetry with the first zigzag pattern; a charge blocking layer, a charge storage layer and a tunnel dielectric layer below the gate; and source and drain regions each formed outside both sides of the gate.

### BACKGROUND OF THE INVENTION

1. Field of the Invention

The present invention relates to semiconductor devices, more particularly, the present invention relates to a nonvolatile memory device including a memory cell array for performing a 2-bit operation and a method of fabricating the same.

2. Description of the Related Art

Nonvolatile memory devices and flash memory devices generally require a high memory density. Extensive research has accordingly been conducted to reduce the size of memory cells and to increase the number of available states of a memory cell.

For example, research has been directed at performing a 2-bit operation in one memory transistor structure. Also, research has been directed at performing a 2-bit operation using a Silicon-Oxide-Nitride-Oxide-Silicon (SONOS) transistor having a charge storage layer between a gate and a semiconductor substrate in a structure that includes a silicon nitride layer. It is believed that such a SONOS transistor may permit 2-bit operation by forward and reverse reading of a threshold voltage Vth, due to the presence of stored charges at different locations.

However, in order for a transistor to perform a 2-bit operation, two independent bit lines should be connected to one transistor cell. In this case, downsizing a device requiring a smaller cell area requires a new cell arranging technique to reduce the contact area of a portion where a bit line and a source/drain region of a transistor are connected.

Thus, it is expected that two bit lines and a word line required for the operation of a one cell transistor should intersect. This expectation arises because this intersecting arrangement between the bit lines and the word line allows channel engineering, such as halo doping, which is advantageous for improving the operating speed of a cell transistor. However, new technologies are required that are more amenable to increasingly smaller semiconductor geometries.

### SUMMARY OF THE INVENTION

The invention is therefore directed to a nonvolatile memory device capable of performing a 2-bit operation that substantially overcomes one or more of the problems due to the limitations and disadvantages of the related art.

At least one of the above and other features and advantages of the invention may be realized by providing a nonvolatile memory device, the nonvolatile memory device including active regions extending in a word line direction in a semiconductor substrate and defined in a first zigzag pattern, gates extending in the word line direction on the semiconductor substrate and formed in a second zigzag pattern which repeatedly intersects the active regions in reverse symmetry with the first zigzag pattern, a charge storage layer provided between the gates and the semiconductor substrate, a charge blocking layer formed on an interface between the charge storage layer and the gates, a tunnel dielectric layer formed on an interface between the charge storage layer and the active region, and source and drain regions formed in portions of the active region exposed outside both sides of the gates.

The device, in part, may further include buried bit lines formed in the semiconductor substrate to overlap the source and drain regions and intersect with the word line direction. The charge storage layer may include two charge storage locations at each gate. The charge storage layer may be formed from a polysilicon layer, a silicon dot, a silicon-germanium layer, or a nano crystal. The charge storage layer may include a pair of local patterns physically isolated from each other below the gate adjacent to each source and drain region. The word lines and the buried bit lines may intersect in a matrix configuration, and the device may further include word line contacts connected to ends of the gates, and bit line contacts electrically connected to the buried bit lines. Two local patterns of a charge storage layer may be physically isolated from each other below the gate adjacent to each source and drain region.

At least one of the above and other features and advantages of the invention may be realized by providing a method of fabricating a nonvolatile memory device, the method including forming a device separation layer to define active regions extending in a word line direction in a semiconductor substrate and defined in a first zigzag pattern, sequentially forming a tunnel dielectric layer, a charge storage layer, and a charge blocking layer on the semiconductor substrate, forming a conductive layer for a gate on the charge blocking layer, forming gates extending in the word line direction and defining a second zigzag pattern to partially and repeatedly intersect the active regions in reverse symmetry with the first zigzag pattern by sequentially selectively etching the conductive layer, the charge blocking layer, the charge storage layer, and the tunnel dielectric layer, forming patterns of the charge blocking layer, the charge storage layer, and the tunnel dielectric layer, and forming source and drain regions connected to the buried bit lines in portions of the active region exposed outside both sides of the gate.

The method may further include forming buried bit lines in the semiconductor substrate to intersect the active regions. The forming of the device separation layer may include forming a trench to define active regions in a first zigzag pattern in the semiconductor substrate, and forming an insulating layer to fill the trench.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1 through 4 illustrate schematic plan views of a cell array of a nonvolatile memory device capable of performing a 2-bit operation according to a first embodiment of the invention;

FIGS. 5 through 10 illustrate cross-sectional views of stages in a method of fabricating the nonvolatile memory device according to the first embodiment of the invention;

FIGS. 11 and 12 illustrate schematic plan views of a cell array of a nonvolatile memory device capable of performing a 2-bit operation according to a second embodiment of the invention;

FIGS. 13 through 20 illustrate cross-sectional views of steps in a method of fabricating the nonvolatile memory according to the second embodiment of the invention; and

FIGS. 21 through 25 illustrate schematic cross-sectional views of a nonvolatile memory device performing a 2-bit operation and a method of fabricating the same according to a third embodiment of the invention.

### DETAILED DESCRIPTION OF THE INVENTION

Korean Patent Application No. 10-2006-0043948, filed on May 16, 2006, in the Korean Intellectual Property Office, and entitled: “Nonvolatile Memory Device Performing 2-Bit Operation and Method of Manufacturing the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

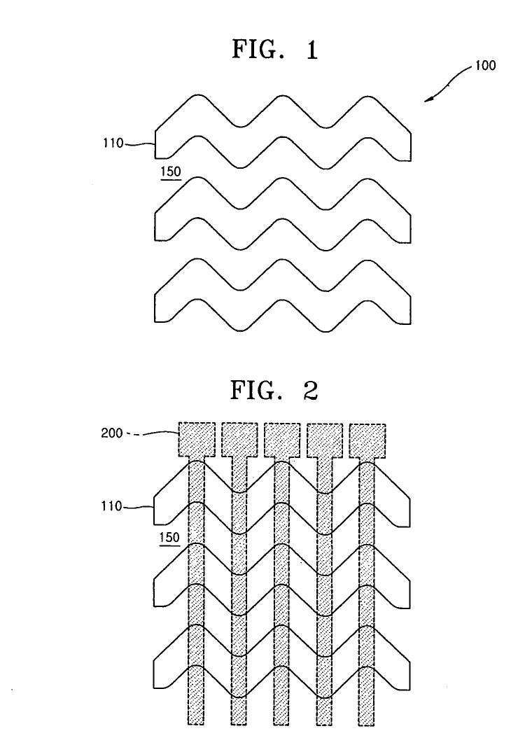

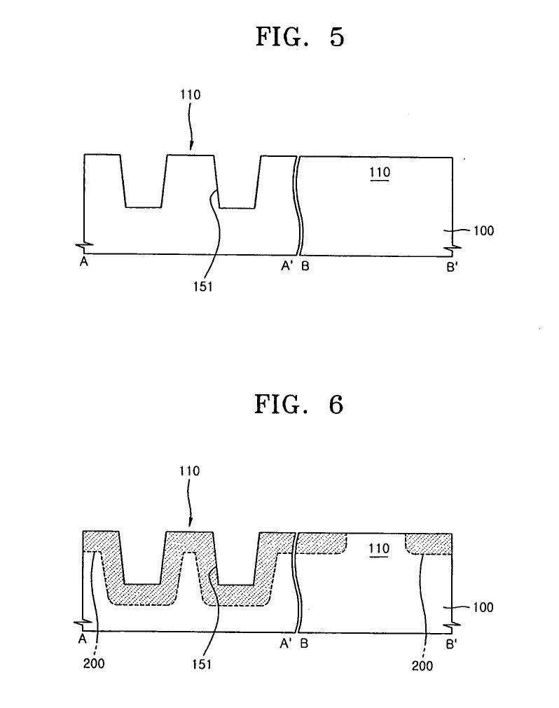

FIGS. 1 through 4 illustrate schematic plan views of a cell array of a nonvolatile memory device capable of performing a 2-bit operation according to a first embodiment of the invention. FIGS. 5 through 10 illustrate cross-sectional views in stages of a method of making the memory device taken along lines A-A′ and B-B′ of FIG. 4.

FIG. 1 illustrates active regions 110 having a first zigzag pattern defined in a semiconductor substrate 100. Each active region 110 may have a shape of a line extending in a predetermined direction, e.g., in a word line (WL) direction, and the first zigzag pattern may have repeatedly bent zigzag portions. The active region 110 may be defined by a device separation region 150.

The device separation region 150 may be realized using, e.g., Shallow Trench Isolation (STI). For example, FIG. 5 illustrates a trench 151 for defining the device separation region 150, which defines the active region 110 conforming to an active layout (as illustrated in FIG. 1). This trench 151 may be formed, e.g., by selectively etching on the semiconductor substrate 100. The semiconductor substrate may preferably be a bulk silicon wafer or a Silicon-On-Insulator (SOI) wafer.

FIG. 2 illustrates multiple buried bit lines (BLs) 200 formed to intersect the active regions 110. The buried bit lines 200 may intersect bent portions of the zigzag pattern of the active regions 110. For a 2-bit operation, two bit lines may be required for one memory cell, and source/drain regions may be defined in the bent portion of each active region 110. Accordingly, each buried bit line 200 may overlap the source/drain regions.

In this case, the buried bit line 200 may include a separate conductive layer buried in the substrate 100. The buried bit line 200 may include a buried bit line which has a conductivity resulting from an impurities layer formed by implanting impurities into the semiconductor substrate 100 through a selective impurity doping process, e.g., a selective ion implantation process. This doping-based formation process is simple and advantageous to implement.

The trenches 151 for the device separation region 150 may be formed in the semiconductor substrate 100, and the buried bit lines 200 may extend across the trenches 151. Since the buried bit lines 200 may be formed by a doping method, the buried bit lines 200 may extend along the sidewalls and bottom of the trenches 151, as illustrated in FIG. 6. In this case, the buried bit lines 200 may have a top surface exposed on a surface of the semiconductor substrate 100.

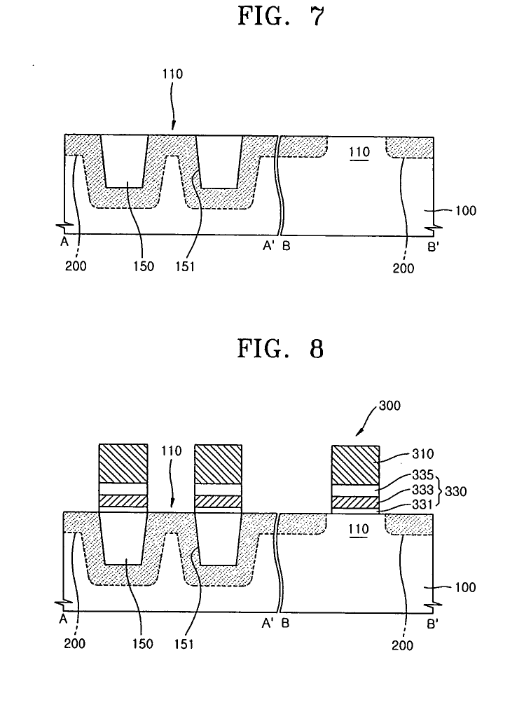

FIGS. 2 and 7 illustrate an insulating layer filling the trenches 151 that may be formed to create the device separation regions 150. Thus, the device separation region 150 may have an STI structure. In this case, the buried bit line 200 may extend below sides and bottom of the device separation regions 150, as shown in FIG. 7.

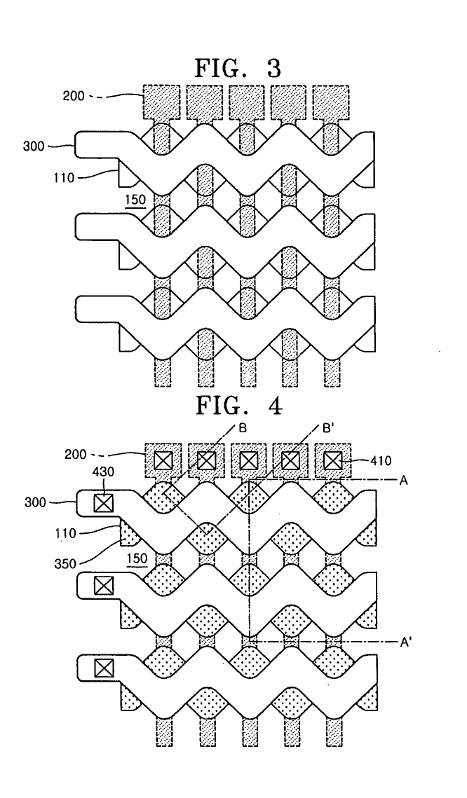

FIG. 3 illustrates that the nonvolatile memory device according to the first embodiment of the invention may include gates that may be word lines (WLs) 300 defined in a second zigzag pattern having an inverted symmetry in relationship to the active regions 110 of the first zigzag pattern. The gates, i.e., the word lines 300, may have a line shape extending in a certain direction, e.g., a word line direction, and may have a second zigzag pattern having repeatedly zigzag bent portions, as shown in FIG. 3. That is, the first and second zigzag patterns may have alternating or reverse zigzag symmetries. In other words, the symmetries may be such that the ‘elbows’ of the first and second zigzag patterns point in opposite directions.

In this case, the second zigzag pattern of the word line 300 may have an up and down (or left and right) symmetry with respect to the first zigzag pattern of the active region 110. For example, if the first zigzag pattern of the active region 110 is bent in a right handed direction, the second zigzag pattern of the word line 300 may be bent in a left handed direction.

The word line 300 having the second zigzag pattern may overlap the active region 110 having the first zigzag pattern such that both patterns partially intersect. In this case, intersecting portions repeatedly appear in the word line direction. Since the second zigzag pattern of the word line 300 may be symmetrical with the first zigzag pattern of the active region 110, the intersecting and non-intersecting portions of the active region 110 that are exposed at both sides of the word line 300 may appear in the word line direction.

Specifically, as illustrated in FIGS. 3 and 8, a layered structure 330 for charge storage may be formed on the semiconductor substrate 100 having the active regions 110 defined by the device separation regions 150. For example, a tunnel dielectric layer 331, for tunneling of charges, e.g., electrons, may be formed on the semiconductor substrate 100. The tunnel dielectric layer 331 may include a silicon oxide layer.

A charge storage layer 333 may be formed on the tunnel dielectric layer 331, and may include a material, e.g., a silicon nitride layer, capable of capturing tunneled and implanted electrons. The charge storage layer 333 may also be formed from a polysilicon layer, a silicon dot, a silicon germanium layer, or a nano crystal.

A charge blocking layer 335 may be formed on the charge storage layer 333 to block charges from back-tunneling during an erasing operation of the nonvolatile memory device. The charge blocking layer 335 may include, e.g., a silicon oxide layer. For example, the layered structure of the tunnel dielectric layer 331, the charge storage layer 333, and the charge blocking layer 335 may be an oxide-nitride-oxide (ONO) structure or an oxide-silicon-oxide (OSO) structure. The layered structure 330 for charge storage may be one of several structures or include at least one of several materials capable of storing charges.

A conductive layer (not shown) may then be formed on the charge blocking layer 335. This conductive layer may include, for example, a conductive polysilicon layer. Subsequently, the conductive layer and the layered structure 330 for charge storage may be selectively removed, e.g., etched, to form a gate 310 that functions as the word line 300 having the second zigzag pattern and the underlying layered structure 330 for charge storage, as shown in FIG. 3.

In this case, portions of the active region 110 having the first zigzag pattern exposed at both sides of the word line 300 may serve as source/drain regions. Also, the buried bit lines 200 intersecting and overlapping the exposed portions of the active region 110 may extend to intersect the word line 300.

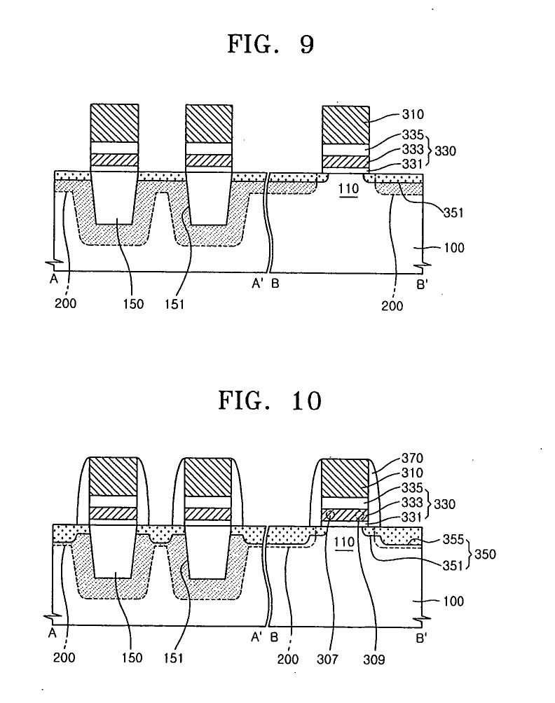

FIGS. 4 and 9 illustrate portions of the active region 110 of the first zigzag pattern exposed at both sides of the word line 300 that may be doped with impurities through a first ion implantation process to form first source and drain regions 351. In this case, since the portions of the active region 110 of the first zigzag pattern exposed at both sides of the word line 300 may be defined and exposed by the gates 310 and the device separation region 150, the gates 310 may be used as ion implantation masks during the first impurity implantation process.

The impurity layer of the first source and drain region 351 may overlap the impurity layer of the buried bit line 200. Accordingly, the first source and drain region 351 and the buried bit line 200 may be electrically connected without using a separate contact structure. The impurity layer of the first source and drain region 351 may have a depth profile irrespective of the impurity layer of the buried bit line 200. The first source and drain region 351 may have a Lightly Doped Drain (LDD) structure obtained by halo doping. The impurity layer of the first source and drain region 351 may have a smaller depth profile, compared to the impurity layer of the buried bit line 200.

FIGS. 4 and 10 illustrate a spacer 370 formed on sidewalls of a stack of the gate 310 and the charge storage layered structure 330 through a spacer formation process. For example, the spacer 370 may be formed by providing an insulating layer and then anisotropically etching, e.g., by using a dry etching method on the insulating layer.

The portion of the active region 110 exposed by the spacer 370 may then be subject to a second impurity ion implantation process to form an impurity layer of a second source and drain region 355. In this case, the impurity layer of the second source and drain region 355 may have a greater depth profile than that of the impurity layer of the first source and drain region 351. The impurity layer of the second source and drain region 355 may also have a smaller depth profile than the impurity layer of the buried bit line 200. The impurity layer of the second source and drain region 355 may be electrically connected to the impurity layer of the buried bit line 200 because of their overlapping structure.

The source and drain region 350 may thus overlap the buried bit line 200 and may be naturally electrically connected thereto. Since a read and/or write operation in a transistor structure performing a 2-bit operation may be performed in a forward or reverse direction, each source and drain region 350 may serve as both a source region and a drain region. That is, since forward and reverse read and/or write operations may be allowed, charges may be independently stored in two charge storage locations 307 and 309 of the charge storage layer 333 adjacent to the source and drain region 350, as shown in FIG. 10.

Thereafter, referring to FIG. 4, an interlayer insulating layer (not shown) may then be formed to cover the gate 310. Then, a word line contact 410 may be formed to pass through the interlayer insulating layer to electrically connect to an end of the buried bit line 200. A bit line contact 430, connected to an end of each word line 300, i.e., the gate 310, may be formed to pass through the interlayer insulating layer. The word line contacts 410 for the word lines 300 and the bit line contacts 430 for the bit lines 200 may be arranged at different sides of a cell area that include memory cells. For example, the word line contacts 410 may be arranged adjacent to a first side of the rectangular cell area, and the bit line contacts 430 may be arranged adjacent to a second side perpendicular to the first side.

In this manner, since the cell array may be constructed so that the word lines 300 and the bit lines 200 intersect, the word lines 300 and the bit lines 200 may be arranged in a matrix form. This matrix form allows simply allocating a specific memory cell from the memory cell matrix by selecting a specific word line 300 and a specific bit line 200. As a result, the word line contacts 410 and the bit line contacts 430 may be separately arranged in different areas, as illustrated in FIG. 4. It is thus possible to simply lay out the contacts 410, 430 in a core region and/or a peripheral region adjacent to the cell area, thereby avoiding problems arising from having a complex core region and/or peripheral region.

Meanwhile, as an integration density of a device significantly increases, the charge storage locations 307 and 309 may become very dense and close to each other. Accordingly, tail portions of charge distributions stored in the respective charge storage locations 307 and 309 may overlap each other. This may cause interference such as crosstalk. A charge storage structure may therefore be considered in which the charge storage locations 307 and 309 may be physically isolated from each other.

This physically symmetric, isolated charge storage structure may be obtained by patterning the charge storage layer when forming the gate 320.

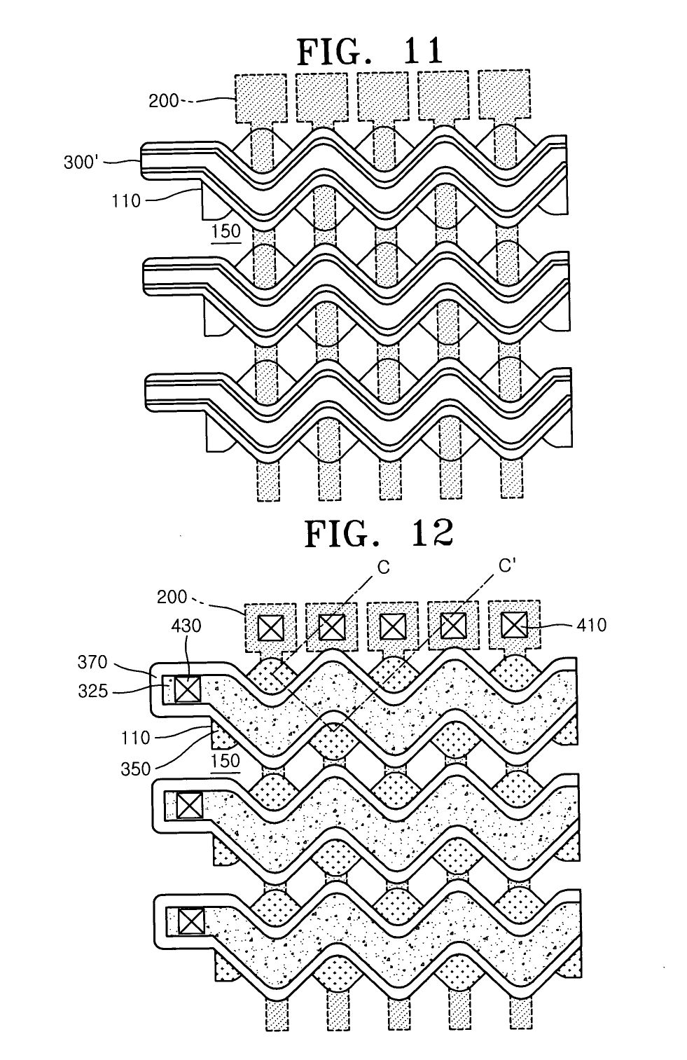

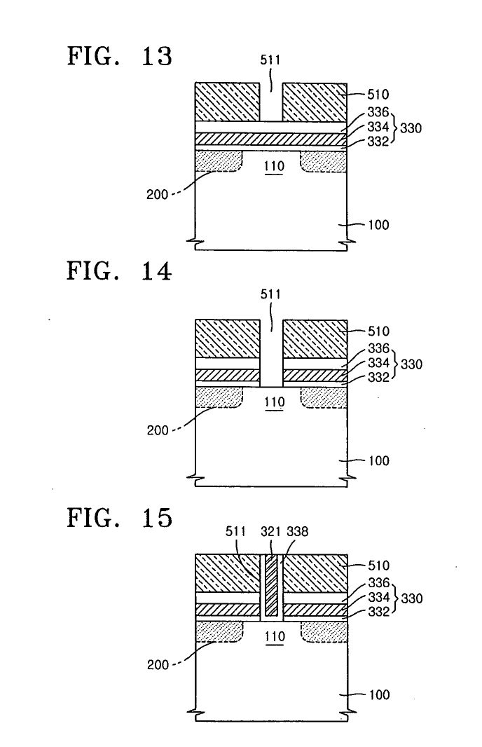

FIGS. 11 and 12 illustrate schematic plan views of a cell array of a nonvolatile memory device performing a 2-bit operation according to a second embodiment of the invention. FIGS. 13 through 20 illustrate cross-sectional views of stages of a method for making the nonvolatile memory device taken along line C-C′ of FIG. 12.

FIGS. 11 and 20 illustrate that each gate 320 of a word line 300′ may include three patterns including a first intermediate gate pattern 321, and two second gate patterns 323 having a spacer shape at both sides. When the gate 320 is formed, an underlying charge storage layer below the gate 320 may be patterned to have a physically isolated structure.

FIGS. 11 and 13 illustrate the device separation region 150 defining the active region 110, conforming to the active layout as shown in FIG. 1, that is formed on the semiconductor substrate 100.

Specifically, the trench 151 may be formed as illustrated in FIG. 5, and then the buried bit line 200 may be formed as illustrated in FIGS. 2 and 6. The device separation region 150 may then be formed, as illustrated in FIG. 7.

A layered structure 330′ for charge storage may then be formed on the semiconductor substrate 100. That is, as illustrated in FIG. 13, a tunnel dielectric layer 332, a charge storage layer 334, and a charge blocking layer 336 may be sequentially formed on the charge storage layer 334. For example, the layered structure 330′ for charge storage may be an ONO structure. The charge storage layer 334 may also be formed from a polysilicon layer, a silicon dot, a silicon germanium layer, or a nano crystal.

A first sacrificial layer 510, which may serve as a framework for shaping a first gate pattern 321 of a gate 320 of word line 300′ (see FIGS. 11 and 13-20), may then be formed on the charge blocking layer 336. The first sacrificial layer 510 may be patterned to have a first opening 511 for the first gate pattern 321 conforming to the second zigzag pattern of the word line 300′. The first opening 511 may have a smaller line width than that of the subsequently formed word line 300′. The first opening 511 may have the same line width of the first gate pattern 321 of the word line 300′ as shown in FIG. 11, and conform to the zigzag pattern of the word line 300′.

As a result, the first opening 511 of the first sacrificial layer 510 may have a zigzag pattern which intersects the active region (110 in FIG. 1), and may expose a portion of the charge blocking layer 336, as illustrated in FIG. 13. The first sacrificial layer 510 may include an insulating material, e.g., silicon nitride, having etch selectivity with respect to an oxide layer constituting the charge blocking layer 336 or a conductive polysilicon layer in the gate structure. The first sacrificial layer 510 may include a silicon oxide layer. In this case, the silicon oxide layer may have a relatively lower density to achieve a higher etch selectivity compared to an oxide layer constituting the charge blocking layer 336.

FIGS. 11 and 14 illustrate that, after the first sacrificial layer 510 is formed, the exposed portion of the charge blocking layer 336 may be selectively removed, e.g., etched, using the first sacrificial layer 510 as an etch mask. Exposed portions of the charge storage layer 334 and the tunnel dielectric layer 332 may then be selectively removed. Accordingly, as shown in FIG. 14, the stacked structure of the tunnel dielectric layer 332, the charge storage layer 334, and the charge blocking layer 336 may be divided into two parts. A portion of the active region 110 of the semiconductor substrate 100 may accordingly by exposed, as illustrated in FIG. 14.

FIGS. 11 and 15 illustrate a gate dielectric layer 338 that may be formed on the semiconductor substrate 100 exposed by the first opening 511 of the first sacrificial layer 510. This gate dielectric layer 338 may be located on an interface between the subsequent gate and the active region 110 of the semiconductor substrate 100. The gate dielectric layer 338 may include a silicon oxide layer and may extend to cover sidewalls of the first sacrifice layer 510. This silicon oxide layer may be formed through a deposition process, e.g., chemical vapor deposition (CVD), or by a thermal oxidation process.

A first gate pattern 321 may then be formed on the gate dielectric layer 338 to fill the first opening 511 of the first sacrificial layer 510. This first gate pattern 321 may form an intermediate portion of the word line 300 of FIG. 11. The first gate pattern 321 may be formed by forming a conductive layer, filling the first opening 511 and planarizing, e.g., through chemical mechanical polishing (CMP) the conductive layer. The first gate pattern 321 may include a conductive material, e.g., polysilicon, a fully silicided layer, or a metal layer, to form the gate of the transistor.

FIGS. 11 and 16 illustrate that the first sacrificial layer 510 may be selectively removed after the first gate pattern 321 is formed. Accordingly, the top surface of the underlying charge blocking layer 336 covered by the first sacrificial layer 510 may be exposed. Also, although not shown in this view, a portion of the active region 110, and a portion of the device separation region 150 may be exposed.

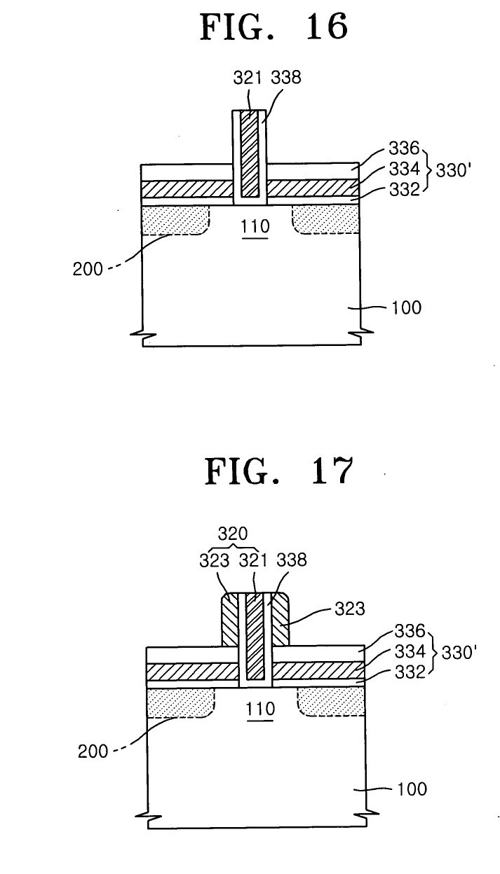

FIGS. 11 and 17 illustrate a second gate pattern 323 having a spacer shape may be formed on the sidewalls of the gate dielectric layer 338 exposed by removing the first sacrificial layer 510. For example, the second gate pattern 323 may be formed to have a spacer shape by forming a conductive layer, such as a polysilicon layer, a silicide layer or a metal layer. Then, an isotropic etch may be performed on the conductive layer. In this manner, the gate 320, including the three patterns of the first gate pattern 321 and the second gate patterns 323, may be formed as the word line 300′ of the second zigzag pattern, as illustrated in FIG. 11.

FIGS. 11 and 18 illustrate a portion of the charge blocking layer 336, which may be exposed outside the word line 300′ or gate 320, may be removed using the first gate pattern 321 and the second gate patterns 323 as etch masks. Portions of the charge storage layer 334 and the tunnel dielectric layer 332 may then be removed.

Accordingly, as illustrated in FIG. 18, the charge storage layer 334 may be formed into local patterns below the second gate pattern 323, and the local patterns may be locally isolated from each other by the first gate pattern 321 and the gate dielectric layer 338. The local charge storage layer patterns 334 may be symmetrical to and may be physically isolated from each other. This gate geometry prevents charges stored in one of the local charge storage layer patterns 334 from affecting a storage state of charges stored in the other local charge storage layer pattern 334.

As the charge storage layer 334 is patterned, the charge blocking layer 336 and the tunnel dielectric layer pattern 332 on and beneath the charge storage layer 334 may be similarly patterned into local patterns aligned with the second gate pattern 323.

After the charge storage layer 334 is patterned into the local patterns, impurities may be implanted into the exposed region of the active region 110 adjacent to the word line 300 or gate 320 by using the word line 300 or gate 320 as an ion implantation mask to form first source and drain region 351, as illustrated in FIG. 9.

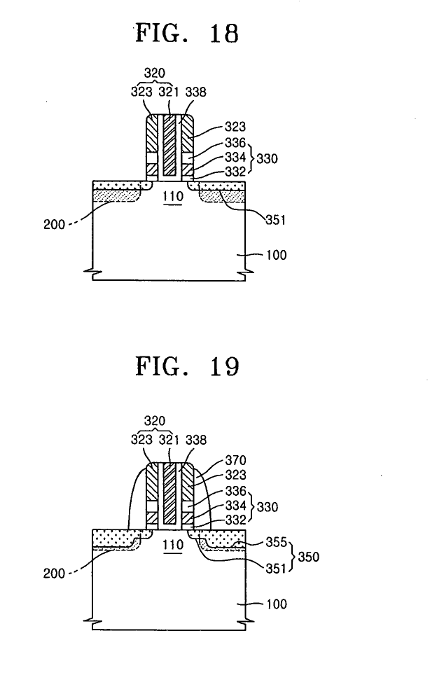

FIGS. 12 and 19 illustrate that the spacer 370 may be formed to cover and protect the exposed sidewalls of the word line 300 or gate 320 and the charge storage layer pattern 334. This spacer 370 may include an insulating material, e.g., a silicon nitride layer and/or a silicon oxide layer.

An ion implantation process using the spacer 370 as an ion implantation mask may be performed in the portion of the active region 110 exposed by the insulating spacer 370, as illustrated in FIG. 10, in order to form a second source and drain region 355. This results in a source/drain region 350 having an LDD structure.

FIGS. 12 and 20 illustrate that a conductive gate silicide layer 325 may be formed in the upper portion of the word line 300 or gate 320 to improve the conductivity of the word line 300 or gate 320. For example, when the word line 300 or gate 320 includes polysilicon, the gate silicide layer 325 may be formed by forming a metal layer on the exposed top surface of the word line 300 or gate 320, and then reacting the polysilicon and the metal layer to form the gate silicon layer 325. In this case, this silicidation reaction may also be also performed on the source and drain region 350 exposed to the insulating spacer 370, resulting in a source and drain silicide layer 357.

The local patterns of the charge storage layer 334 may be physically isolated at both sides below the word line 300 or gate 320. The local patterns of the charge storage layer 334 may also be aligned with the second gate pattern 323 when the first gate pattern 321 and the second gate pattern 323 having an outer spacer shape adhered thereto are formed, as in the second embodiment of the invention. Such a method may be modified by one having ordinary skill in the art.

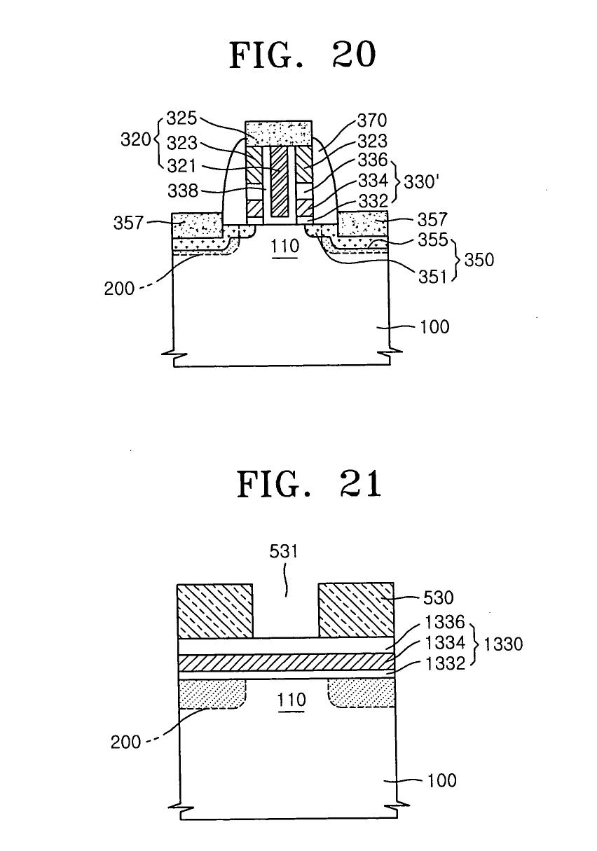

FIGS. 21 through 25 illustrate schematic cross-sectional views of stages in a method for forming a nonvolatile memory device performing a 2-bit operation and a method of fabricating the same, according to a third embodiment of the invention.

FIG. 21 illustrates the active region 110, conforming to the active layout as depicted in FIG. 1, defined in the semiconductor substrate 100. The buried bit line 200 and the device separation region 150 may be formed as illustrated in FIGS. 11 and 13.

A layered structure 1330 for charge storage may then be formed on the semiconductor substrate 100, as is similarly illustrated in FIG. 13. That is, FIG. 21 illustrates that a tunnel dielectric layer 1332, a charge storage layer 1334, and a charge blocking layer 1336 may be sequentially formed on the charge storage layer 1334. For example, the layered structure 1330 may have an ONO structure.

As a framework for shaping the gate 1320 of the word line 300, a second sacrificial layer 530 may be formed on the charge blocking layer 1336. The second sacrificial layer 530 may be patterned to have a second opening 531 conforming to the second zigzag pattern of the word line or gate 320. The second opening 531 may have the same line width as the word line or gate 320.

Due to the presence of the second opening 531 of the second sacrificial layer 530, the active region (110 in FIG. 1) may be formed in a zigzag pattern, and portions of the charge blocking layer 1336 may be exposed. The second sacrificial layer 530 may include an insulating material, e.g., silicon nitride, having etch selectivity with respect to an oxide layer forming the charge blocking layer 1336 or the polysilicon layer forming the word line or gate 320. The second sacrificial layer 530 may include a silicon oxide layer, which may have a relatively low density to provide higher etch selectivity relative to the oxide layer, forming the charge blocking layer 1336.

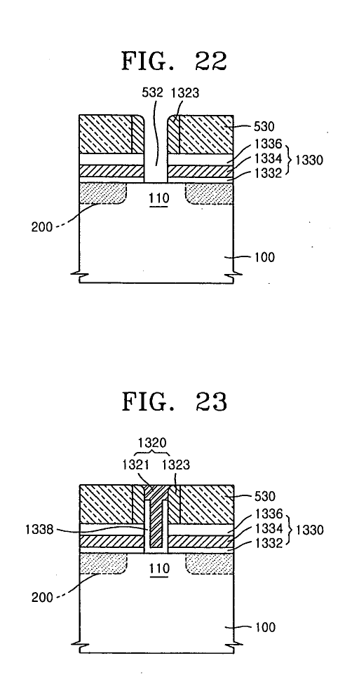

FIG. 22 illustrates that after the second sacrificial layer 530 is formed, a third gate pattern 1323 may be formed to have a spacer shape such that the third gate pattern 1323 adheres to the inner sidewall of the second opening 531. The third gate pattern 1323 may be formed through a spacer etching process in which a conductive layer, e.g., a polysilicon layer, may be deposited and anisotropically dry-etched. Since the third gate pattern 1323 having a spacer shape may adhere to the sidewall of the second opening 531, the third opening 532 may have a smaller line width than the second opening 531.

Then, the exposed portion of the charge blocking layer 1336 may be selectively removed using the third gate pattern 1323 and the second sacrifice layer 530 as masks. Subsequently, the exposed portions of the underlying charge storage layer 1334 and the tunnel dielectric layer 1332 may be selectively etched. Accordingly, the stacked structure of the tunnel dielectric layer 1332, the charge storage layer 1334, and the charge blocking layer 1336 may be divided into two parts, as illustrated in FIG. 22. Accordingly, a portion of the underlying active region 110 in the lower semiconductor substrate 100 may be exposed.

FIG. 23 illustrates a gate dielectric layer 1338 that may be formed on the semiconductor substrate 100 exposed in the third opening 532. This gate dielectric layer 1338 may be located on an interface between a second gate pattern, described below, and the active region 110 of the semiconductor substrate 100. The gate dielectric layer 1338 may include a silicon oxide layer, and the gate dielectric layer 1338 may extend to cover the sidewall of the first gate pattern 1321. For example, the gate dielectric layer 1338 may be formed by depositing a silicon oxide layer by a deposition process, such as chemical vapor deposition (CVD), or by a thermal oxidation process.

A fourth gate pattern 1321 may then be formed on the gate dielectric layer 1338 to fill the third opening 532. The fourth gate pattern 1321 may form an intermediate portion of a word line. In this case, the fourth gate pattern 1321 may be formed by forming a conductive layer, e.g., a polysilicon layer, to fill the third opening 532 and then planarizing, for example, through CMP. The fourth gate pattern 1321 may include a conductive material used to form the gate of the transistor, e.g., a polysilicon layer, a full silicide layer, or a metal layer.

In this case, the third gate pattern 1323 and the fourth gate pattern 1321 may be electrically connected. This electrical connection may be achieved by preventing the gate dielectric layer 1338 from extending to the top surface or upper sidewall of the third gate pattern 1323. For example, when a conductive layer for the fourth gate pattern 1321 is deposited, the third opening 532 may be partially filled with the conductive layer, and the exposed upper portion of the gate dielectric layer 1338 may then be selectively removed. Afterwards, the conductive layer for the fourth gate pattern 1321 may again be deposited to completely fill the third opening 532. The conductive layer is then planarized to obtain the structure of the gate 1320, as illustrated in FIG. 23.

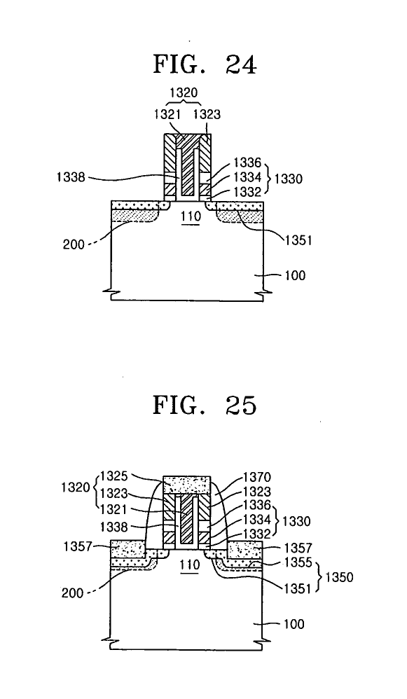

FIG. 24 illustrates that the second sacrificial layer 530 may be selectively removed after the fourth gate pattern 1321 is formed. This process exposes the upper surface of the underlying charge blocking layer 1336, as illustrated in FIG. 17. The portion of the charge blocking layer 1336 exposed outside the both sides of the gate 1320 may then be removed using the fourth gate pattern 1321 and the third gate pattern 1323 as masks. Subsequently, the exposed portions of the charge storage layer 1334 and the tunnel dielectric layer 1332 may be removed.

Accordingly, as illustrated in FIG. 24, a charge storage layer 1334 may be formed into two local patterns below the third gate pattern 1323, which are locally isolated from each other by the fourth gate pattern 1321 and the gate dielectric layer 1338. The local charge storage layer patterns 1334 may be symmetrical with and physically isolated from each other. Accordingly, charges stored in one of the local charge storage layer patterns 1334 do not affect the storage state of charges stored in the other local charge storage layer pattern 1334. That is, the charge storage layer patterns 1334 at each gate 1320 may independently hold two charges, thus permitting 2-bit operation.

As the charge storage layer 1334 is patterned, the charge blocking layer 1336 and the tunnel dielectric layer pattern 1332 on and beneath the charge storage layer pattern 1334 may be likewise patterned into local patterns aligned with the third gate pattern 1323.

After the charge storage layer 1334 is patterned into the local patterns described above, impurities may be implanted into the exposed region of the active region 110 adjacent to the gate 1320, using the gate 1320 as an ion implantation mask, to form a first source and drain region 1351, as illustrated in FIG. 24.

FIG. 25 illustrates a sidewall insulating spacer 1370 that may be formed, to cover and protect the exposed sidewalls of the gate 1320 and the charge storage layer pattern 1334. This insulating spacer 1370 may include a silicon nitride layer and/or a silicon oxide layer.

An ion implantation process using the insulating spacer 1370 as an ion implantation mask may then be performed, to form a second source and drain region 1355 in the active region 110 portion exposed by the insulating spacer 1370. This process results in a source/drain region 1350 having an LDD structure.

A silicidation process may then be performed to improve the conductivity of the gate 1320, similar to the process illustrated in FIGS. 12 and 20. This process may form a conductive gate silicide layer 1325 in an upper portion of the gate 1320, along with source and drain silicide layers 1357 on the sides of the insulating spacer 1370.

As described in the second and third embodiments of the invention, the gates 320′ and 1320 may include three patterns, and the two charge storage layer patterns 334 and 1334 may be formed as local patterns aligned with the second gate pattern 323 or the third gate pattern 1323. The local charge storage layer patterns 334 and 1334 may be physically isolated from and additionally be symmetrical with each other at both sides below the gates 320′ and 1320. This semiconductor geometry may physically prevent charges stored in each storage location from overlapping, as in the case of related art devices having small geometries. It is thus possible to suppress unwanted interferences such as crosstalk during 2-bit operation.

The cell transistors formed according to the embodiments of the present invention may be laid out for a NAND or NOR flash memory device.

According to embodiments of the present invention, a nonvolatile memory device may have an array of word lines and bit lines, and an array of active regions for performing a 2-bit operation. An array of memory cells, each having a word line, a first bit line, and a second bit line, which are independent from each other, may perform a 2-bit operation. Each memory cell may include one transistor structure, which may include a gate, first and second source/drain regions, and charge storage layers. The first and second source/drain regions may face each other with a channel interposed below the gate. The charge storage layers may extend to cover the entire channel regions. The charge storage layers may be formed in regions adjacent to first and second source/drain regions beneath the gate to be physically and symmetrically isolated from each other. When the charge storage layers are symmetrical with and physically isolated from each other, distributions of charges stored in the regions adjacent to the first and second source/drain regions do not overlap each other, thereby physically preventing generation of crosstalk between cells.

In embodiments of the present invention, the word line may extend in substantially the same direction as an extending direction of a region on a semiconductor substrate, e.g., an active region, in which a transistor structure is formed. Accordingly, several memory cells may be connected to one word line and a number of bit lines may be arranged in parallel and spaced apart. In this case, the active region may extend in the word line direction. The word line and the active region may overlap in part. The other portion of the active region may be exposed at both sides of the word line. For example, the word line and the active region may be formed in a zigzag pattern.

The first zigzag pattern for the active region and the second zigzag pattern for the word line may repeatedly intersect. In addition, the active region may be partially exposed between the intersecting regions. One memory cell may be formed on this intersecting region. Further, the active region portion exposed to the word line, which is adjacent to an area at which the word line and the active region intersect, may be electrically connected to the bit line. For example, the first zigzag pattern for the active region may be repeatedly bent in a right hand direction, and the word line may be repeatedly bent in a left hand direction. When the first and second zigzag patterns overlap on a plane, they have partially intersecting portions. The underlying zigzag pattern may have non-intersecting portions that are exposed.

Also, the first and second bit lines may intersect the word line. The first and second bit lines may be connected to one memory cell. Pairs of the bit lines may be repeatedly formed and may intersect one corresponding word line. In this case, the first and second bit lines are buried bit lines that overlap an impurities region, i.e., a source and drain region formed by doping the active region exposed to both sides of the word line, may be electrically connected and extend to intersect the word line. In this case, the buried bit line may be formed by selective impurity doping in the semiconductor substrate, e.g., selective ion implantation.

Since the buried bit line may directly overlap and be in contact with the source and drain regions, a contact area may be secured with no restriction, unlike a contact structure for connecting the bit line to the source and drain. Thus, contacts may be effectively secured even though the cell area of a device is reduced. This allows for a further reduced cell area of the device.

According to embodiments of the present invention, as the word lines and the active regions may be formed in a zigzag pattern, cells may be laid out in such a manner that the word lines and the bit lines intersect each other in a matrix. This geometry allows for utilization of channel engineering, such as halo doping, to suppress a short channel effect and/or to enhance program speed.

The contacts connected to the word lines and/or the bit lines may be separately arranged for the word lines and the bit lines. This may simplify the layout of pads in the core region and/or the peripheral region around the cells, thereby solving problems arising from complex core and peripheral regions.

Buried bit lines may be used, and the source and drain regions formed in the active region may be brought into contact with the buried bit lines with no restriction on contact area. This feature allows a device to be downsized while securing good electrical connections between the bit lines and the source and drain regions.

Furthermore, in a transistor forming a cell of a nonvolatile memory device, the charge storage layer or storage node for storing charges may be formed into locally isolated patterns at both sides below the gate. That is, each gate may independently hold two or more charges. This feature may prevent overlapping distributions of the charges stored in the charge storage layers and, in turn, disturbance of 2-bit operation. That is, in the cell transistor, the physically isolated storage nodes below one word line may suppress charge interference between bits in the cell. Accordingly, the expected advantages of a nonvolatile memory device performing a 2-bit operation may be assured, and the integration density of a device is not limited due to charge interference phenomena. Thus, it is possible to further increase the integration density of a nonvolatile memory device.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A nonvolatile memory device, comprising:
active regions extending in a word line direction in a semiconductor substrate and defined in a first zigzag pattern;
gates extending in the word line direction on the semiconductor substrate and defined in a second zigzag pattern, the second zigzag pattern repeatedly intersecting the active regions in reverse symmetry with the first zigzag pattern;
a charge storage layer provided between the gates and the semiconductor substrate;
a charge blocking layer provided between the charge storage layer and the gates;
a tunnel dielectric layer provided between the charge storage layer and the active region; and
source and drain regions each formed in a portion of the active region exposed outside both sides of the gates.

2. The device as claimed in claim 1, wherein the charge storage layer comprises two charge storage locations at each gate.

3. The device as claimed in claim 1, further comprising buried bit lines formed in the semiconductor substrate, the buried bit lines overlapping the source and drain regions and intersecting the word line direction.

4. The device as claimed in claim 3, wherein the word lines and the buried bit lines intersect in a matrix form, and
the device further comprises;
word line contacts connected to ends of the gates; and
bit line contacts electrically connected to the buried bit lines.

5. The device as claimed in claim 1, wherein the charge storage layer includes a silicon nitride layer, and the charge blocking layer and the tunnel dielectric layer each include a silicon oxide layer.

6. The device as claimed in claim 1, wherein the charge storage layer comprises a polysilicon layer, a silicon dot, a silicon germanium layer, or a nano crystal.

7. The device as claimed in claim 1, wherein the charge storage layer includes two local patterns physically isolated from each other below the gate adjacent to each source and drain region.

8. The device as claimed in claim 7, wherein the gate extends on the portion of the active portion between the two isolated local patterns of the charge storage layer, and
the device further comprises:
a gate dielectric layer formed on an interface between the portion of the gate extending between the local patterns of the charge storage layer and the portion of the active region; and
the two local patterns of the charge storage layer are physically isolated from each other by the gate dielectric layer and the extending portion of the gate.

9. The device as claimed in claim 7, wherein the gate comprises:
a first gate pattern aligned on the portion of the active portion between the two isolated local patterns of the charge storage layer;
two second gate patterns aligned on the two isolated local patterns of the charge storage layer; and
a gate dielectric layer formed on an interface between the first gate pattern and the portion of the active region.

10. The device as claimed in claim 9, wherein the gate dielectric layer extends on a side interface between the first gate pattern and the second gate patterns.

11. The device as claimed in claim 9, further comprising an upper gate silicide layer formed for electrical connection of the first gate pattern and the second gate pattern.

12. A method of fabricating a nonvolatile memory device, comprising:
forming a device separation layer to define active regions extending in a word line direction in a semiconductor substrate and defining a first zigzag pattern;
sequentially forming a tunnel dielectric layer, a charge storage layer, and a charge blocking layer on the semiconductor substrate;
forming a conductive layer for a gate on the charge blocking layer;
forming a gate extending in the word line direction and defining a second zigzag pattern, the second zigzag pattern partially and repeatedly intersecting the active regions in reverse symmetry with the first zigzag pattern by sequentially selectively etching the conductive layer, the charge blocking layer, the charge storage layer, and the tunnel dielectric layer, and forming patterns of the charge blocking layer, the charge storage layer, and the tunnel dielectric layer; and
forming source and drain regions in portions of the active region exposed outside both sides of the gate.

13. The method as claimed in claim 12, further comprising forming buried bit lines that are buried in the semiconductor substrate to intersect the active regions, and the buried bit lines are connected to the source and drain regions.

14. The method as claimed in claim 13, further comprising:
forming an interlayer insulating layer to cover the semiconductor substrate, wherein the word lines and the buried bit lines intersect in a matrix form by passing through the interlayer insulating layer; and
forming word line contacts connected to ends of the gates and arranged in a row, and bit line contacts electrically connected to the buried bit lines.

15. The method as claimed in claim 12, wherein the forming of the device separation layer comprises:
forming a trench to define the active region in the first zigzag pattern in the semiconductor substrate; and
forming an insulating layer in the trench.

16. The method as claimed in claim 12, wherein the charge storage layer includes a silicon nitride layer, and the charge blocking layer and the tunnel dielectric layer include a silicon oxide layer.

17. The method as claimed in claim 12, wherein charge storage layer comprises a layer including a polysilicon layer, a silicon dot, a silicon germanium layer, or a nano crystal.

18. The method of claim 12, wherein the charge storage layer comprises two charge storage locations at each gate.

19. The method as claimed in claim 12, further comprising:
forming a sacrificial layer on the charge blocking layer, the sacrificial layer extending in the word line direction and having the second zigzag pattern;
selectively removing exposed portions of the charge blocking layer, the charge storage layer, and the tunnel dielectric layer using the sacrificial layer as a mask to expose portions of the active regions and the device separation region;
forming a gate dielectric layer on the exposed portion of the active region;
forming a first gate pattern on the gate dielectric layer to fill the opening;
selectively removing the sacrificial layer;
forming a second gate pattern adhered on a sidewall of the first gate pattern to form a gate, the second gate pattern having a spacer shape; and
selectively removing the charge blocking layer, the charge storage layer and the tunnel dielectric layer using the gate as a mask to form patterns of the charge blocking layer, a pair of local patterns of the charge storage layer that are physically isolated from each other below the gate, and patterns of the tunnel dielectric layer.

20. The method of claim 12, further comprising:
forming buried bit lines that are buried in the semiconductor substrate to intersect the active regions;
forming, on the charge blocking layer, a sacrificial layer having an opening extending in the word line direction and having the second zigzag pattern;
forming a first gate pattern having a spacer shape on an inner sidewall of the opening;
selectively removing exposed portions of the charge blocking layer, the charge storage layer, and the tunnel dielectric layer using the sacrificial layer and the first gate pattern as masks to expose portions of the active region and the device separation layer;
forming a gate dielectric layer on the exposed portion of the active region;
forming, on the gate dielectric layer, a second gate pattern filling the opening to form a gate;
selectively removing the sacrificial layer pattern; and
selectively removing exposed portions of the charge blocking layer, the charge storage layer, and the tunnel dielectric layer using the gate as a mask to form patterns of the charge blocking layer, a pair of local patterns of the charge storage layer that are physically isolated from each other below the gate, and patterns of the tunnel dielectric layer.
